(19) United States
(12) Patent Application Publication
(10) Pub. No.: US 2026/0150689 A1
(43) Pub. Date: May 28, 2026

(54) SEMICONDUCTOR PACKAGE

(71) Applicant: Samsung Electronics Co., Ltd., Suwon-si (KR)

(72) Inventors: Dawoon Jung, Suwon-si (KR); Haseob Seong, Suwon-si (KR)

(21) Appl. No.: 19/269,562

(22) Filed: Jul. 15, 2025

(30) Foreign Application Priority Data
Nov. 22, 2024 (KR) 10-2024-0168916

(51) Int. Cl. H01L 23/00; H01L 23/31; H01L 23/48; H01L 25/04

(52) U.S. Cl. CPC H10W 42/121; H10W 20/20; H10W 74/131; H10W 90/00; H10W 90/792

(57) ABSTRACT

Semiconductor packages and methods to form the semiconductor packages are provided. In one aspect, a semiconductor package includes a first semiconductor substrate, a stacked structure including second semiconductor substrates arranged on the first semiconductor substrate and sequentially stacked, and a plurality of chip-to-chip bonding layers respectively arranged between the plurality of second semiconductor substrates, a lowermost bonding layer including side surfaces aligned with side surfaces of the first semiconductor substrate in a vertical direction, and arranged between a first semiconductor substrate and a lowermost second semiconductor substrate of the stacked structure, a support insulating layer arranged on the lowermost bonding layer, and including an upper surface having a higher vertical level than a vertical level of an upper surface of the lowermost second semiconductor substrate, and a molding layer arranged on the lowermost bonding layer, and configured to surround the support insulating layer and the stacked structure.

### CROSS-REFERENCE TO RELATED APPLICATION(S)

This application is based on and claims priority under 35 U.S.C. § 119 to Korean Patent Application No. 10-2024-0168916, filed on Nov. 22, 2024, in the Korean Intellectual Property office, the disclosure of which is incorporated by reference herein in its entirety.

### BACKGROUND

In response to the rapid development of the electronics industry and the needs of users, electronic devices are being miniaturized, multi-functionalized, and equipped with a large capacity. Accordingly, highly integrated semiconductor chips are desired. Semiconductor packages have been designed to include highly integrated semiconductor chips with an increased number of input/output (I/O) connection terminals while securing connection reliability.

### SUMMARY

The present disclosure provides a semiconductor package capable of restricting a peeling phenomenon between stacked semiconductor chips.

However, issues to be solved by the present disclosure are not limited to the above-mentioned issues, and other issues not mentioned may be clearly understood by those of ordinary skill in the art from the following descriptions.

According to according to an aspect of the present disclosure, a semiconductor package includes a first semiconductor substrate, a stacked structure including a plurality of second semiconductor substrates arranged on the first semiconductor substrate and sequentially stacked, and a plurality of chip-to-chip bonding layers respectively arranged between the plurality of second semiconductor substrates, a lowermost bonding layer including side surfaces aligned with side surfaces of the first semiconductor substrate in a vertical direction, and arranged between a first semiconductor substrate and a lowermost second semiconductor substrate of the stacked structure, a support insulating layer arranged on the lowermost bonding layer, and including an upper surface having a higher vertical level than a vertical level of an upper surface of the lowermost second semiconductor substrate, and a molding layer arranged on the lowermost bonding layer, and configured to surround the support insulating layer and the stacked structure.

According to another aspect of the present disclosure, a semiconductor package includes a first semiconductor chip including a first semiconductor substrate, a first through via configured to penetrate the first semiconductor substrate, and a first upper wiring structure arranged on an upper surface of the first semiconductor substrate, a stacked structure arranged on the first semiconductor chip and including a plurality of second semiconductor chips sequentially stacked, wherein each of the plurality of second semiconductor chips includes a second semiconductor substrate, a second through via configured to penetrate the second semiconductor substrate, a second lower wiring structure arranged under the second semiconductor structure, and a second upper wiring structure arranged on an upper surface of the second semiconductor chip, a support insulating layer arranged on the first semiconductor chip, and configured to surround at least a portion of side surfaces of the plurality of second semiconductor chips of the stacked structure, and a molding layer arranged on the first semiconductor chip, and configured to surround the support insulating layer and the stacked structure.

According to according to another aspect of the present disclosure, a semiconductor package includes a first semiconductor substrate, a stacked structure including a plurality of second semiconductor substrates arranged on the first semiconductor substrate and sequentially stacked, and a plurality of chip-to-chip bonding layers respectively arranged between the plurality of second semiconductor substrates, a lowermost bonding layer including side surfaces aligned with side surfaces of the first semiconductor substrate in a vertical direction, and arranged between the first semiconductor substrate and a lowermost second semiconductor substrate of the stacked structure, a support insulating layer arranged on the lowermost bonding layer, and configured to surround a portion of side surfaces of the stacked structure, and a molding layer arranged on the lowermost bonding layer, and configured to surround the support insulating layer and the stacked structure, wherein each of the plurality of chip-to-chip bonding layers includes a chip-to-chip bonding insulating layer configured to fill spaces between each of the plurality of second semiconductor substrates, and a chip-to-chip bonding pad arranged inside the chip-to-chip bonding insulating layer, wherein the lowermost bonding layer includes a lowermost bonding pad and a lowermost bonding insulating layer configured to surround the lowermost bonding pad, wherein a vertical level of an upper surface of the support insulating layer is lower than a vertical level of an upper surface of a target chip-to-chip bonding layer, and higher than a vertical level of a lower surface of the target chip-to-chip bonding layer, and wherein the target chip-to-chip bonding layer includes a chip-to-chip bonding layer arranged on one layer among first through fourth layers among the plurality of chip-to-chip bonding layers.

### BRIEF DESCRIPTION OF THE DRAWINGS

Implementations will be more clearly understood from the following detailed description taken in conjunction with the accompanying drawings in which:

FIG. 1 is a schematic cross-sectional view of a semiconductor package according to an implementation;

FIG. 2 is a schematic enlarged view of region EX1 in the semiconductor package of FIG. 1;

FIG. 3 is a schematic enlarged view of region EX2 in the semiconductor package of FIG. 1;

FIG. 4 is a schematic enlarged view of region EX3 in the semiconductor package of FIG. 1;

FIG. 5 is a schematic enlarged view of a portion of a semiconductor package, according to an implementation;

FIG. 6 is a schematic cross-sectional view of a semiconductor package according to an implementation;

FIG. 7 is a schematic cross-sectional view of a semiconductor package according to an implementation; and

FIGS. 8A through 8J are cross-sectional views illustrating a method of manufacturing a semiconductor package, according to implementations.

### DETAILED DESCRIPTION

Implementations of the present disclosure are provided to more completely explain the

technical idea of the present disclosure to those of ordinary skill in the art, the implementations below may be modified in various different forms, and the scope of the technical idea of the present disclosure is not limited thereto. Rather, the implementations are provided to make the present disclosure more faithful and complete, and to fully convey the technical idea of the present disclosure to those of ordinary skill in the art.

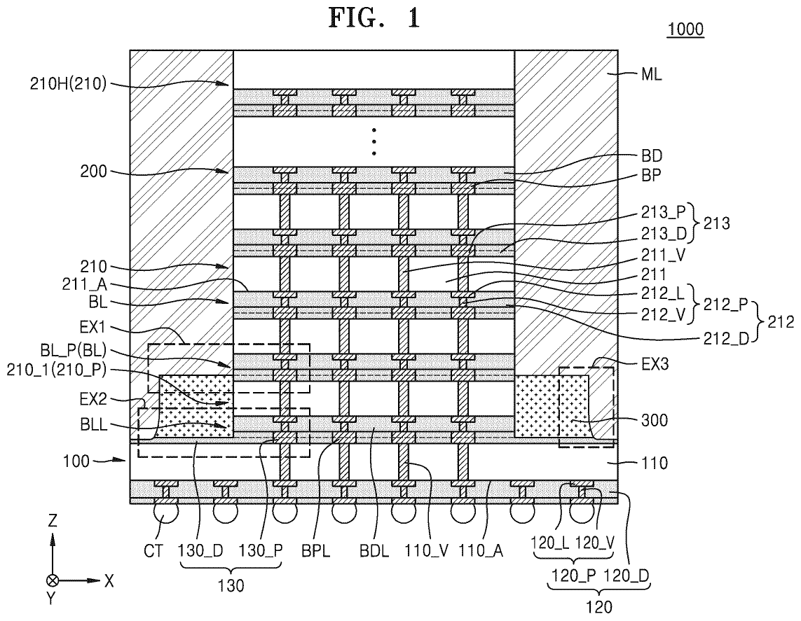

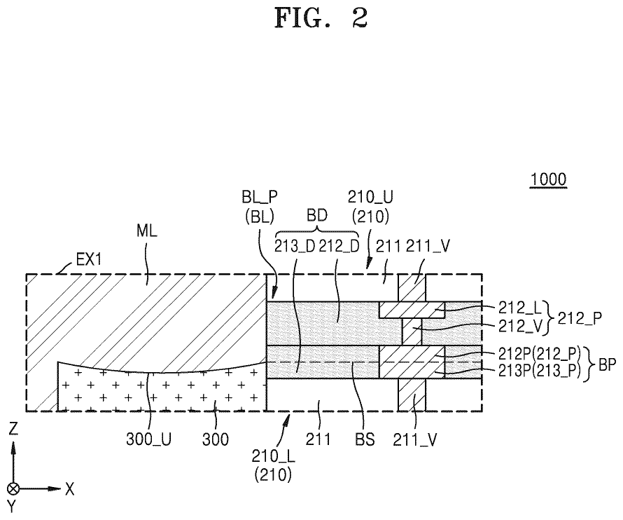

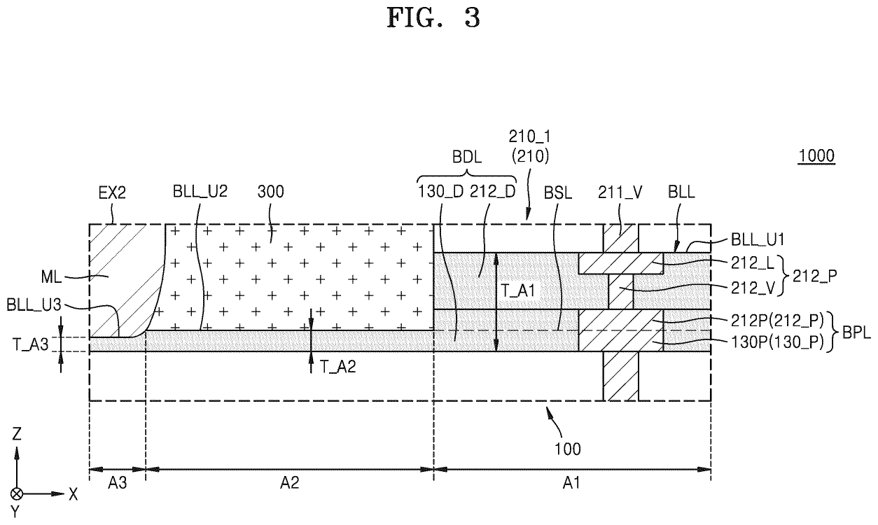

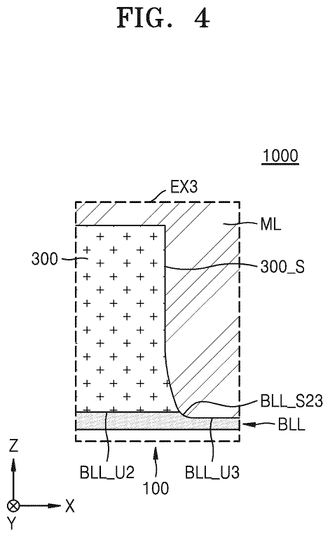

FIG. 1 is a schematic cross-sectional view of a semiconductor package 1000 according to an implementation. FIG. 2 is a schematic enlarged view of region EX1 in the semiconductor package 1000 of FIG. 1. FIG. 3 is a schematic enlarged view of region EX2 in the semiconductor package 1000 of FIG. 1. FIG. 4 is a schematic enlarged view of region EX3 in the semiconductor package 1000 of FIG. 1.

Referring to FIGS. 1 through 4, the semiconductor package 1000 may include a first semiconductor chip 100, a stacked structure 200, a support insulating layer 300, and a molding layer ML.

Hereinafter, unless otherwise defined, a direction in parallel with a lower surface of the first semiconductor chip 100 may be defined as a first horizontal direction (X direction), a direction perpendicular to the lower surface of the first semiconductor chip 100 may be defined as a vertical direction (Z direction), and a direction perpendicular to the first horizontal direction (X direction) and the vertical direction (Z direction) may be defined as a second horizontal direction (Y direction). A horizontal direction may be defined as a direction in which the first horizontal direction (X direction) and the second horizontal direction (Y direction) are combined.

The first semiconductor chip 100 may include a first semiconductor substrate 110, a first through via 110_V, a first lower wiring structure 120, and a first upper wiring structure 130.

The first semiconductor substrate 110 may include an active surface 110_A and an inactive surface, which are opposite to each other. In some implementations, the active surface 110_A of the first semiconductor substrate 110 may be referred to as a front surface of the first semiconductor substrate 110, and an inactive surface of the first semiconductor substrate 110 may be referred to as a back surface of the first semiconductor substrate 110.

For example, the first semiconductor substrate 110 may include, for example, a semiconductor material such as silicon (Si). Alternatively, the first semiconductor substrate 110 may include a semiconductor material such as germanium (Ge).

A semiconductor device including a plurality of individual devices of various types may be formed on the active surface 110_A of the first semiconductor substrate 110. The plurality of individual devices of the first semiconductor substrate 110 may include various microelectronic devices, for example, a metal-oxide-semiconductor field effect transistor (MOSFET) such as a complementary metal-oxide semiconductor (CMOS) transistor, system large scale integration (LSI), an image sensor such as a CMOS imaging sensor (CIS), a micro-electro-mechanical system (MEMS), an active device, a passive device, etc.

The first lower wiring structure 120 may be arranged on the lower surface of the first semiconductor substrate 110. The first lower wiring structure 120 may include a first lower wiring pattern 120_P and a first lower wiring insulating layer 120_D surrounding the first lower wiring pattern 120_P.

The first lower wiring pattern 120_P may include a first lower wiring line 120_L extending in the horizontal direction and a first lower wiring via 120_V extending from the first lower wiring line 120_L in the vertical direction (Z direction). The first lower wiring pattern 120_P may be electrically connected to the plurality of individual devices of the first semiconductor substrate 110.

For example, a portion of the first lower wiring line 120_L that is arranged at the lowermost end of the first lower wiring lines 120_L and exposed to the outside of the first lower wiring insulating layer 120_D may be referred to as a first lower pad. External connection terminals CT may be attached to the first lower pad.

The first upper wiring structure 130 may be arranged on an upper surface of the first semiconductor substrate 110. The first upper wiring structure 130 may include a first upper wiring pattern 130_P and a first upper wiring insulating layer 130_D surrounding the first upper wiring pattern 130_P. For example, a portion of the first upper wiring pattern 130_P that is arranged at the uppermost end of the first upper wiring patterns 130_P and exposed to the outside of the first upper wiring insulating layer 130_D may be referred to as a first upper pad 130P. For example, a portion of the first upper wiring insulating layer 130_D surrounding side surfaces of the first upper pad 130P may be referred to as a first upper passivation layer. Although the first upper wiring structure 130 is illustrated as a single layer in FIG. 1, the first upper wiring structure 130 may have a multi-layered structure like the first lower wiring structure 120. For example, the first upper wiring pattern 130_P of the first upper wiring structure 130 may include first upper wiring lines arranged on different layers and extending in the horizontal direction, and first upper wiring vias electrically connecting the first upper wiring lines to each other arranged on different layers.

The first through via 110_V may extend from the active surface 110_A of the first semiconductor substrate 110 to the inactive surface of the first semiconductor substrate 110. For example, the first through via 110_V may electrically connect the first upper wiring structure 130 to the first lower wiring structure 120. Although the first through via 110_V is illustrated to be distinguished from the first lower wiring pattern 120_P and the first upper wiring pattern 130_P in FIG. 1, the first through via 110_V may be formed with the first lower wiring pattern 120_P and the first upper wiring pattern 130_P into one body.

In some implementations, the first lower wiring pattern 120_P, the first upper wiring pattern 130_P, and the first through via 110_V may include copper, nickel, stainless steel, or beryllium copper.

The stacked structure 200 may be arranged on the first semiconductor chip 100. The stacked structure 200 may include a plurality of second semiconductor chips 210. The plurality of second semiconductor chips 210 may be sequentially stacked. For example, in the plurality of second semiconductor chips 210, a lowermost second semiconductor chip 210_1 at the lowermost end thereof may be referred to as a first layer, and the other second semiconductor chips 210 may be referred to as nth layers in an ascending order. In an example, first to fourth layers can be between a fifth layer and the first semiconductor chip 100.

In some implementations, the stacked structure 200 may include 8 to 20 second semiconductor chips 210. However, the implementation is not limited thereto, and the stacked structure 200 may include four or more second semiconductor chips 210.

In some implementations, the first semiconductor chip 100 may include a semiconductor chip including a serial-parallel conversion circuit and configured to control the second semiconductor chips 210, and the second semiconductor chip 210 may include a memory chip including memory cells.

In some implementations, the semiconductor package 1000 may include a high bandwidth memory (HBM), the first semiconductor chip 100 may be referred to as an HBM controller die, and the second semiconductor chip 210 may be referred to as a dynamic random access memory (RAM) (DRAM) die.

Each of the plurality of second semiconductor chips 210 may include a second semiconductor substrate 211, a second lower wiring structure 212, and a second upper wiring structure 213. A thickness of the second semiconductor chip 210, that is, a length thereof in the vertical direction (Z direction), may be about 20 μm to about 80 μm. For example, among the plurality of second semiconductor chips 210, a thickness of an uppermost second semiconductor chip 210H arranged at the uppermost layer of the plurality of second semiconductor chips 210 may be greater than thicknesses of the other second semiconductor chips 210.

The second semiconductor substrate 211 may include an active surface 211_A and an inactive surface opposite thereto. For example, the second semiconductor substrate 211 may include a semiconductor material, such as Si and Ge. The second semiconductor substrate 211 may include a compound semiconductor material, such as silicon carbide (SiC), gallium arsenide (GaAs), indium arsenide (InAs), and indium phosphate (InP).

A semiconductor device including a plurality of individual devices of various types may be formed on the active surface 211_A of the second semiconductor substrate 211. The plurality of individual devices of the second semiconductor substrate 211 may include various microelectronic devices, for example, a MOSFET such as a CMOS transistor, an LSI, an image sensor such as a CIS, an MEMS, an active device, a passive device, etc.

The second lower wiring structure 212 may be arranged under a lower surface of the second semiconductor substrate 211. The second lower wiring structure 212 may include a second lower wiring pattern 212_P and a second lower wiring insulating layer 212_D surrounding the second lower wiring pattern 212_P.

The second lower wiring pattern 212_P may include a second lower wiring line 212_L and a second lower wiring via 212_V. The second lower wiring pattern 212_P may include the second lower wiring line 212_L extending in the horizontal direction and the second lower wiring via 212_V extending in the vertical direction (Z direction) from the second lower wiring line 212_L. A portion of the second lower wiring line 212_L arranged at the lowermost end of the second lower wiring lines 212_L and exposed to the outside of the second lower wiring insulating layer 212_D may be referred to as a second lower pad 212P. For example, a portion of the second lower wiring insulating layer 212_D surrounding side surfaces of the second lower pad 212P may be referred to as a second lower passivation layer.

The second upper wiring structure 213 may be arranged on an upper surface of the second semiconductor substrate 211. The second upper wiring structure 213 may include a second upper wiring pattern 213_P and a second upper wiring insulating layer 213_D surrounding the second upper wiring pattern 213_P. For example, a portion of the second upper wiring pattern 213_P arranged at the uppermost end of the second upper wiring patterns 213_P and exposed to the outside of the second upper wiring insulating layer 213_D may be referred to as a second upper pad 213P. For example, a portion of the second upper wiring insulating layer 213_D surrounding side surfaces of the second upper pad 213P may be referred to as a second upper passivation layer.

Although the first upper wiring structure 130 is illustrated as a single layer in FIG. 1, the first upper wiring structure 130 may have a multilayer structure like the first lower wiring structure 120. For example, the first upper wiring pattern 130_P of the first upper wiring structure 130 may include first upper wiring lines arranged on different layers and extending in the horizontal direction, and first upper wiring vias electrically connecting the first upper wiring lines arranged on different layers to each other.

A second through via 211_V may extend from the inactive surface of the second semiconductor substrate 211 to the active surface 211_A. The second through via 211_V may electrically connect the second lower wiring structure 212 to the second upper wiring structure 213. Although the second through via 211_V is illustrated to be distinguished from the second lower wiring pattern 212_P and the second upper wiring pattern 213_P in FIG. 1, the second through via 211_V may be formed with the second lower wiring pattern 212_P and the second upper wiring pattern 213_P into one body.

In some implementations, the second lower wiring pattern 212_P, the second upper wiring pattern 213_P, and the second through via 211_V may include copper, nickel, stainless steel, or beryllium copper.

Hereinafter, a lowermost bonding layer BLL and a plurality of chip-to-chip bonding layers BL are described.

Referring to FIG. 3, the lowermost bonding layer BLL may be referred to as the first upper wiring structure 130 of the first semiconductor chip 100 and the second lower wiring structure 212 of the lowermost second semiconductor chip 210_1, which are integrated by using a hybrid bonding process.

For example, the lowermost bonding layer BLL may be arranged between the first semiconductor substrate 110 of the first semiconductor chip 100 and the second semiconductor substrate 211 of the lowermost second semiconductor chip 210_1. In the present disclosure, the second semiconductor substrate 211 of the lowermost second semiconductor chip 210_1 may be referred to as the lowermost second semiconductor substrate.

The lowermost bonding layer BLL may include a lowermost bonding pad BPL and a lowermost bonding insulating layer BDL surrounding the lowermost bonding pad BPL. The lowermost bonding pad BPL may be formed by applying a diffusion bonding process using heat on the first upper pad 130P of the first semiconductor chip 100 and the second lower pad 212P of the lowermost second semiconductor chip 210_1. The lowermost bonding insulating layer BDL may be formed by applying a hydrogen bonding process using pressure on the first upper wiring insulating layer 130_D of the first semiconductor chip 100 and the second lower wiring insulating layer 212_D of the lowermost second semiconductor chip 210_1. For example, the first upper passivation layer and the second lower passivation layer may be formed into one body, and thus the lowermost second semiconductor chip 210_1 may be attached to the first semiconductor chip 100.

For example, a surface, on which a hybrid bonding process is applied on the first upper wiring structure 130 of the first semiconductor chip 100 and the second lower wiring structure 212 of the lowermost second semiconductor chip 210_1, that is, a surface, on which the first upper wiring structure 130 of the first semiconductor chip 100 is in contact with the second lower wiring structure 212 of the lowermost second semiconductor chip 210_1, may be referred to as a bonding surface BSL of the lowermost bonding layer BLL.

In some implementations, one side surface of the lowermost bonding layer BLL may be aligned with the side surfaces of the first semiconductor substrate 110 of the first semiconductor chip 100 in the vertical direction (Z direction). For example, the one side surface of the lowermost bonding layer BLL may include a side surface of the first upper wiring insulating layer 130_D of the first upper wiring structure 130 of the first semiconductor chip 100.

Each of the plurality of chip-to-chip bonding layers BL may be arranged between each of the second semiconductor substrates 211 of the plurality of second semiconductor chips 210. In some implementations, the number of chip-to-chip bonding layers BL may be one less than the number of second semiconductor chips 210.

For convenience of description, the chip-to-chip bonding layer BL is described mainly based on an upper layer second semiconductor chip 210_U and a lower layer second semiconductor chip 210_L stacked directly under the upper layer second semiconductor chip 210_U among the plurality of second semiconductor chips 210.

Referring to FIG. 2, the chip-to-chip bonding layer BL may be referred to as the second upper wiring structure 213 of the lower layer second semiconductor chip 210_L and the second lower wiring structure 212 of the upper layer second semiconductor chip 210_U, which are integrated into one body by using the hybrid bonding process. For example, the chip-to-chip bonding layer BL may be arranged between the second semiconductor substrate 211 of the lower layer second semiconductor chip 210_L and the second semiconductor substrate 211 of the upper layer second semiconductor chip 210_U.

The chip-to-chip bonding layer BL may include a chip-to-chip bonding pad BP and a chip-to-chip bonding insulating layer BD surrounding the chip-to-chip bonding pad BP. The chip-to-chip bonding pad BP may be formed by applying a diffusion bonding process using heat on the second upper pad 213P of the lower layer second semiconductor chip 210_L and the second lower pad 212P of the upper layer second semiconductor chip 210_U. The chip-to-chip bonding insulating layer BD may be formed by applying a hydrogen bonding process using pressure on the second upper wiring insulating layer 213_D of the lower layer second semiconductor chip 210_L and the second lower wiring insulating layer 212_D of the upper layer second semiconductor chip 210_U. For example, the second upper passivation layer of the lower layer second semiconductor chip 210_L and the second lower passivation layer of the upper layer second semiconductor chip 210_U may be formed into one body, and thus the lower layer second semiconductor chip 210_L may be attached onto the upper layer second semiconductor chip 210_U. For example, the chip-to-chip bonding insulating layer BD may fill a space between the upper layer second semiconductor chip 210_U and the lower layer second semiconductor chip 210_L. Side surfaces of the chip-to-chip bonding insulating layer BD may be aligned with side surfaces of the upper layer second semiconductor chip 210_U and side surfaces of the lower layer second semiconductor chip 210_L in the vertical direction (Z direction).

For example, a surface, on which a hybrid bonding process is performed on the second upper wiring structure 213 of the lower layer second semiconductor chip 210_L and the second lower wiring structure 212 of the upper layer second semiconductor chip 210_U, that is, a surface, on which the second upper wiring structure 213 of the lower layer second semiconductor chip 210_L is in contact with the second lower wiring structure 212 of the upper layer second semiconductor chip 210_U, may be referred to as a bonding surface BS of the chip-to-chip bonding layer BL.

The side surfaces of the chip-to-chip bonding layer BL, the side surfaces of the second semiconductor substrate 211 of the upper layer second semiconductor chip 210_U, and the second semiconductor substrate 211 of the lower layer second semiconductor chip 210_L may be aligned with each other in the vertical direction (Z direction).

The stacked structure 200, in which the first semiconductor chip 100 and a plurality of second semiconductor chips 210 are sequentially stacked, may include the first semiconductor substrate 110, the lowermost bonding layer BLL arranged on the first semiconductor substrate 110, the lowermost second semiconductor substrate arranged on the lowermost bonding layer BLL, and the chip-to-chip bonding layer BL and the second semiconductor substrate 211 alternately stacked on the lowermost second semiconductor substrate.

Referring to FIG. 2 again, in some implementations, an upper surface 300_U of the support insulating layer 300 may have a concave shape. For example, the support insulating layer 300 may include an inner sidewall in contact with a side surface of the stacked structure 200 and an outer sidewall opposite to the inner sidewall. The upper surface 300_U of the support insulating layer 300 may have a concave shape in which a point having the same separation distance from the inner sidewall and the outer sidewall of the support insulating layer 300 is relatively lowered in the vertical direction (Z direction).

Referring to FIG. 1 again, the support insulating layer 300 may be on the first semiconductor chip 100, and may surround at least a portion of the side surfaces of the stacked structure 200. For example, the support insulating layer 300 may be in contact with an upper surface of the first upper wiring structure 130 of the first semiconductor chip 100, and at the same time, may be in contact with the side surfaces of the stacked structure 200.

The support insulating layer 300 may be arranged on the lowermost bonding layer BLL, and a vertical level of the upper surface 300_U of the support insulating layer 300 may be higher than the upper surface of the second semiconductor substrate 211 of the lowermost second semiconductor chip 210_1. In some implementations, the support insulating layer 300 may entirely cover the side surfaces of the lowermost second semiconductor substrate. In some implementations, the support insulating layer 300 may include silicon oxide or silicon nitride.

A plurality of second semiconductor chips 210 may include a target second semiconductor chip 210_P. The target second semiconductor chip 210_P may include one of the plurality of second semiconductor chips 210. For example, the target second semiconductor chip 210_P may include one of the second semiconductor chips 210 arranged on one of the first through fourth layers among the plurality of second semiconductor chips 210. Referring to FIG. 1, the target second semiconductor chip 210_P may include the second semiconductor chip 210 on the first layer among the plurality of second semiconductor chips 210.

The vertical level of the upper surface of the second upper wiring structure 213 of the target second semiconductor chip 210_P may be the same as the vertical level of the upper surface of the support insulating layer 300. For example, the support insulating layer 300 may cover all side surfaces of the second semiconductor chip 210 arranged below the target second semiconductor chip 210_P among the plurality of second semiconductor chips 210.

In some implementations, a thickness of the target second semiconductor chip 210_P may be less than thicknesses of the other second semiconductor chips 210. For example, a thickness of the second upper wiring structure 213 of the target second semiconductor chip 210_P may be less than a thickness of the second upper wiring structure 213 of the other second semiconductor chips 210.

For example, in the process of manufacturing the semiconductor package 1000, the operation of removing an upper portion of the support insulating layer 300 so that an upper surface of the target second semiconductor chip 210_P is exposed may be included. In this operation, a portion of the target second semiconductor chip 210_P may be removed, and may be thinner than the other second semiconductor chips 210.

The plurality of chip-to-chip bonding layers BL may include a target chip-to-chip bonding layer BL_P. The target chip-to-chip bonding layer BL_P may be on the upper surface of the second semiconductor substrate 211 of the target second semiconductor chip 210_P. For example, the target chip-to-chip bonding layer BL_P may include the second upper wiring structure 213 of the target second semiconductor chip 210_P.

The target chip-to-chip bonding layer BL_P may include one of the plurality of chip-to-chip bonding layers BL. For example, the target chip-to-chip bonding layer BL_P may include one of the chip-to-chip bonding layers BL arranged below the second semiconductor substrate 211 of the second semiconductor chip 210 on the fifth layer among the plurality of chip-to-chip bonding layers BLs in the vertical direction (Z direction). For example, the target chip-to-chip bonding layer BL_P may include one of the chip-to-chip bonding layers BL arranged on one of the first through fourth layers among the plurality of chip-to-chip bonding layers BLs. Referring to FIG. 1, the target chip-to-chip bonding layer BL_P may include the chip-to-chip bonding layer BL on the first layer among the plurality of chip-to-chip bonding layers BL.

In some implementations, the vertical level of the upper surface 300_U of the support insulating layer 300 may be lower than the vertical level of the upper surface of the target chip-to-chip bonding layer BL_P, and may be higher than the vertical level of the lower surface of the target chip-to-chip bonding layer BL_P. In other words, the upper surface 300_U of the support insulating layer 300 is between the upper surface of the target chip-to-chip bonding layer BL_P and the lower surface of the target chip-to-chip bonding layer BL_P along a vertical direction (e.g., Z direction).

In some implementations, a thickness of the target chip-to-chip bonding layer BL_P may be less than thicknesses of the other chip-to-chip bonding layers BL. For example, because the second upper wiring structure 213 of the target second semiconductor chip 210_P is relatively thin, the thickness of the target chip-to-chip bonding layer BL_P including the second upper wiring structure 213 of the target second semiconductor chip 210_P may be relatively small.

With reference to FIGS. 2 and 4, the support insulating layer 300 and the lowermost bonding layer BLL are described.

A side surface 300_S of the support insulating layer 300 may overlap the upper surface of the first semiconductor chip 100 in the vertical direction (Z direction). For example, a width of the support insulating layer 300 may be less than a width of the first semiconductor chip 100.

The lowermost bonding layer BLL may be divided into a center region A1, a connection region A2, and an edge region A3. The center region A1 of the lowermost bonding layer BLL may include a region in which the lowermost bonding layer BLL overlaps the stacked structure 200 in the vertical direction (Z direction), the connection region A2 of the lowermost bonding layer BLL may include a region in which the lowermost bonding layer BLL overlaps the support insulating layer 300 in the vertical direction (Z direction), and the edge region A3 of the lowermost bonding layer BLL may include a region arranged outside the side surface 300_S of the support insulating layer 300. In other words, the edge region A3 can extend beyond the edges of the side surface 300_S of the support insulating layer 300.

For example, an upper surface BLL_U1 of the center region A1 of the lowermost bonding layer BLL may be in contact with the lowermost second semiconductor substrate, an upper surface BLL_U2 of the connection region A2 of the lowermost bonding layer BLL may be in contact with the support insulating layer 300, and an upper surface BLL_U3 of the edge region A3 of the lowermost bonding layer BLL may be in contact with the molding layer ML.

In some implementations, a thickness T_A1 of the center region A1 of the lowermost bonding layer BLL may be greater than a thickness T_A2 of the connection region A2 of the lowermost bonding layer BLL. The thickness T_A2 of the connection region A2 of the lowermost bonding layer BLL may be greater than a thickness T_A3 of the edge region A3 of the lowermost bonding layer BLL.

For example, the second lower wiring structure 212 of the lowermost second semiconductor chip 210_1 may be arranged in the center region A1 of the lowermost bonding layer BLL. Accordingly, the center region A1 of the lowermost bonding layer BLL may be thicker than the connection region A2, by a thickness of the second lower wiring structure 212 of the lowermost second semiconductor chip 210_1.

For example, a portion of the edge region A3 of the lowermost bonding layer BLL may be removed together with the support insulating layer 300 in the process of etching a portion of the support insulating layer 300, and thus the thickness T_A3 of the edge region A3 of the lowermost bonding layer BLL may be less than the thickness T_A2 of the connection region A2.

The first upper wiring structure 130 of the first semiconductor chip 100 may be included in the lowermost bonding layer BLL. A center region of the first upper wiring structure 130 may include a region where the center region A1 of the lowermost bonding layer BLL is arranged, a connection region of the first upper wiring structure 130 may include a region where the connection region A2 of the lowermost bonding layer BLL is arranged, and an edge region of the first upper wiring structure 130 may include a region where the edge region A3 of the lowermost bonding layer BLL is arranged.

The center region of the first upper wiring structure 130 may be in contact with the second lower wiring structure 212 of the lowermost second semiconductor chip 210_1, the connection region of the first upper wiring structure 130 may be in contact with the support insulating layer 300, and the edge region of the first upper wiring structure 130 may be in contact with the molding layer ML.

In some implementations, a thickness of the edge region of the first upper wiring structure 130 may be less than a thickness of the connection region of the first upper wiring structure 130 and a thickness of the edge region of the first upper wiring structure 130.

The lowermost bonding layer BLL may further include a recess side surface BLL_S23. In some implementations, the recess side surface BLL_S23 of the lowermost bonding layer BLL may connect the upper surface BLL_U3 of the edge region A3 of the lowermost bonding layer BLL to the upper surface BLL_U2 of the connection region A2 of the lowermost bonding layer BLL.

The recess side surface BLL_S23 of the lowermost bonding layer BLL may be continuously connected to the side surface 300_S of the support insulating layer 300. For example, the recess side surface BLL_S23 of the lowermost bonding layer BLL and the side surface 300_S of the support insulating layer 300 may be simultaneously formed, and thus the recess side surface BLL_S23 of the lowermost bonding layer BLL may be continuously connected to the side surface 300_S of the support insulating layer 300 without a step therebetween.

In some implementations, the side surface 300_S of the support insulating layer 300 may include a curved side surface having a concave shape. For example, an upper side surface of the support insulating layer 300 may include a flat surface extending in the vertical direction (Z direction), and a lower side surface of the support insulating layer 300 may include a curved surface concave toward the inside of the support insulating layer 300. The recess side surface BLL_S23 of the lowermost bonding layer BLL may be continuously connected to the curved side surface of the support insulating layer 300, and may have a concave shape. The lower side surface of the support insulating layer 300 may also be referred to as a first side surface of the support insulating layer 300 in the present disclosure.

For example, depending on a method in which a portion of the edge region A3 of the lowermost bonding layer BLL and a portion of the support insulating layer 300 are removed, the recess side surface BLL_S23 of the lowermost bonding layer BLL and the side surface of the support insulating layer 300 may have a concave shape.

Referring to FIG. 1 again, the molding layer ML may be on the first semiconductor chip 100, and may surround the support insulating layer 300 and the stacked structure 200. A side surface of the molding layer ML may be aligned with the side surface of the first semiconductor chip 100 in the vertical direction (Z direction), and an upper surface of the molding layer ML may be coplanar with an upper surface of the stacked structure 200.

In other words, the molding layer ML may be arranged on the lowermost bonding layer BLL, and may surround the support insulating layer 300 and the stacked structure 200. The side surface of the molding layer ML, the side surface of the first semiconductor substrate 110, and a side surface of the lowermost bonding layer BLL may be aligned with each other in the vertical direction (Z direction).

In some implementations, the molding layer ML may include an epoxy resin, a polyimide resin, etc. The molding layer ML may include, for example, an epoxy molding compound (EMC).

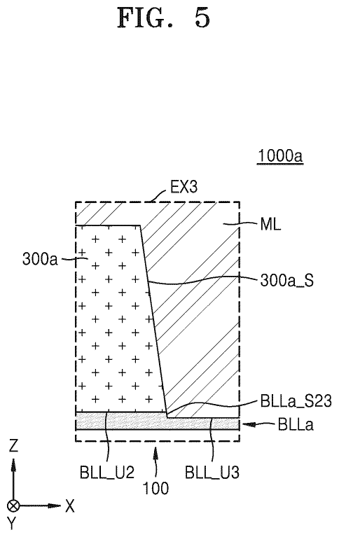

FIG. 5 is a schematic enlarged view of a portion of a semiconductor package 1000a, according to an implementation.

Most of components constituting the semiconductor package 1000a and materials constituting the components to be described below may be substantially the same as or similar to those described above. Accordingly, for convenience of descriptions, the differences between the semiconductor package 1000a of FIG. 5 the semiconductor package 1000 of FIG. 4 described above are mainly described.

There may be a shape difference between a side surface 300a_S of the support insulating layer 300a of the semiconductor package 1000a of FIG. 5 and the side surface 300_S of the support insulating layer 300 of the semiconductor package 1000 of FIG. 4, and there may be a shape difference between a recess side surface BLLa_S23 of a lowermost bonding layer BLLa of the semiconductor package 1000a of FIG. 5 and the recess side surface BLL_S23 of the lowermost bonding layer BLL of the semiconductor package 1000 of FIG. 4.

A width of the support insulating layer 300a may increase toward the lowermost bonding layer BLLa. For example, the side surface 300a_S of the support insulating layer 300a may have a tapered shape. For example, the side surface 300a_S of the support insulating layer 300a may include an inclined surface forming an obtuse angle with an upper surface of the support insulating layer 300a.

The recess side surface BLLa_S23 of the lowermost bonding layer BLLa may be continuously connected to the side surface 300a_S of the support insulating layer 300a. The recess side surface BLLa_S23 of the lowermost bonding layer BLLa may have a tapered shape. For example, a slope of the recess side surface BLLa_S23 of the lowermost bonding layer BLLa may be the same as a slope of the side surface 300a_S of the support insulating layer 300a.

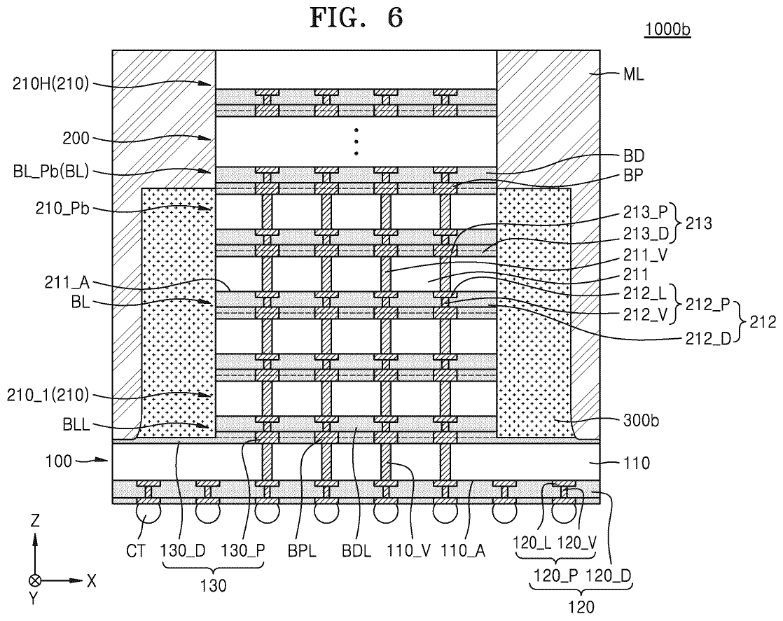

FIG. 6 is a schematic cross-sectional view of a semiconductor package 1000b according to an implementation.

Most of components constituting the semiconductor package 1000b and materials constituting the components to be described below may be substantially the same as or similar to those described above. Accordingly, for convenience of descriptions, the differences between the semiconductor package 1000b of FIG. 6 and the semiconductor package 1000 of FIG. 1 described above are mainly described.

FIG. 1 illustrates the semiconductor package 1000 in which the target second semiconductor chip 210_P may include the second semiconductor chip 210 on the first layer among the plurality of second semiconductor chips 210, and FIG. 6 illustrates the semiconductor package 1000b in which a target second semiconductor chip 210_Pb may include the second semiconductor chip 210 on the fourth layer of the plurality of second semiconductor chips 210.

Referring to FIG. 6, the target second semiconductor chip 210_Pb may include the second semiconductor chip 210 on the fourth layer among the plurality of second semiconductor chips 210. A target chip-to-chip bonding layer BL_Pb may include the chip-to-chip bonding layer BL, arranged on the upper surface of the second semiconductor substrate 211 of the second semiconductor chip 210 arranged on one of four layers, among the plurality of chip-to-chip bonding layers BL.

The second semiconductor chip 210 arranged on the fourth layer among the plurality of second semiconductor chips 210 may be thinner than the second semiconductor chips 210 arranged on the other layers. The chip-to-chip bonding layer BL arranged on the fourth layer among the plurality of chip-to-chip bonding layers BL may be thinner than the chip-to-chip bonding layers BL arranged on the other layers.

A support insulating layer 300b may completely cover the side surfaces of the second semiconductor chips 210 arranged on the first through third layers and the side surfaces of the chip-to-chip bonding layers BL arranged on the first through third layers. A vertical level of an upper surface of the support insulating layer 300b may be higher than a vertical level of the upper surface of the second semiconductor substrate 211 of the second semiconductor chip 210 arranged on the fourth layer among the plurality of second semiconductor chips 210. The vertical level of the upper surface of the support insulating layer 300b may be lower than a vertical level of an upper surface of the chip-to-chip bonding layer BL, and higher than a vertical level of a lower surface of the chip-to-chip bonding layer BL, arranged on the fourth layer among the plurality of chip-to-chip bonding layers BL.

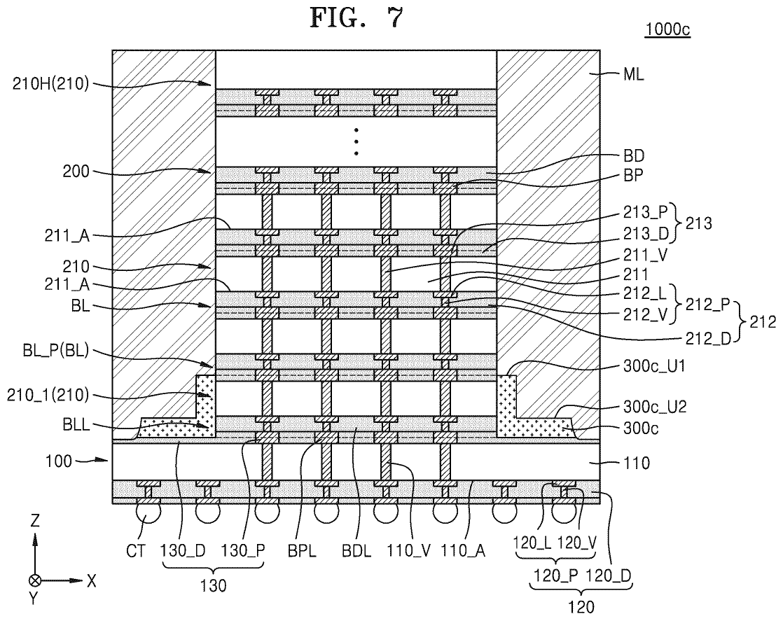

FIG. 7 is a schematic cross-sectional view of a semiconductor package 1000c according to an implementation.

Most of components constituting the semiconductor package 1000c and materials constituting the components to be described below may be substantially the same as or similar to those described above. Accordingly, for convenience of descriptions, the differences between the semiconductor package 1000c of FIG. 7 and the semiconductor package 1000 of FIG. 1 described above are mainly described.

Referring to FIG. 7, the semiconductor package 1000c may include the first semiconductor substrate 110, the lowermost bonding layer BLL arranged on the first semiconductor substrate 110, the stacked structure 200 in which a plurality of second semiconductor substrates 211 arranged above the lowermost bonding layer BLL and the plurality of chip-to-chip insulating layers BL are alternately stacked, a support insulating layer 300c, and a molding layer ML.

The support insulating layer 300c may be arranged on the lowermost bonding layer BLL, and may surround a portion of the side surface of the stacked structure 200. Side surfaces of the support insulating layer 300c may overlap the upper surface of the lowermost bonding layer BLL in the vertical direction (Z direction). A width of the support insulating layer 300c may be less than a width of the lowermost bonding layer BLL.

An upper surface of the support insulating layer 300c may be divided into a first upper surface 300c_U1 and a second upper surface 300c_U2 including a step therebetween. For example, a vertical level of the first upper surface 300c_U1 of the support insulating layer 300c may be higher than a vertical level of the second upper surface 300c_U2 of the support insulating layer 300c.

The first upper surface 300c_U1 of the support insulating layer 300c may be in contact with the side surface of the stacked structure 200, and the second upper surface 300c_U2 of the support insulating layer 300c may be apart from the side surfaces of the stacked structure 200 with the first upper surface 300c_U1 of the support insulating layer 300c therebetween.

In some implementations, the support insulating layer 300c may be conformally formed on the side surfaces of the lowermost bonding layer BLL and the stacked structure 200. For example, the support insulating layer 300c may have an “L” shape.

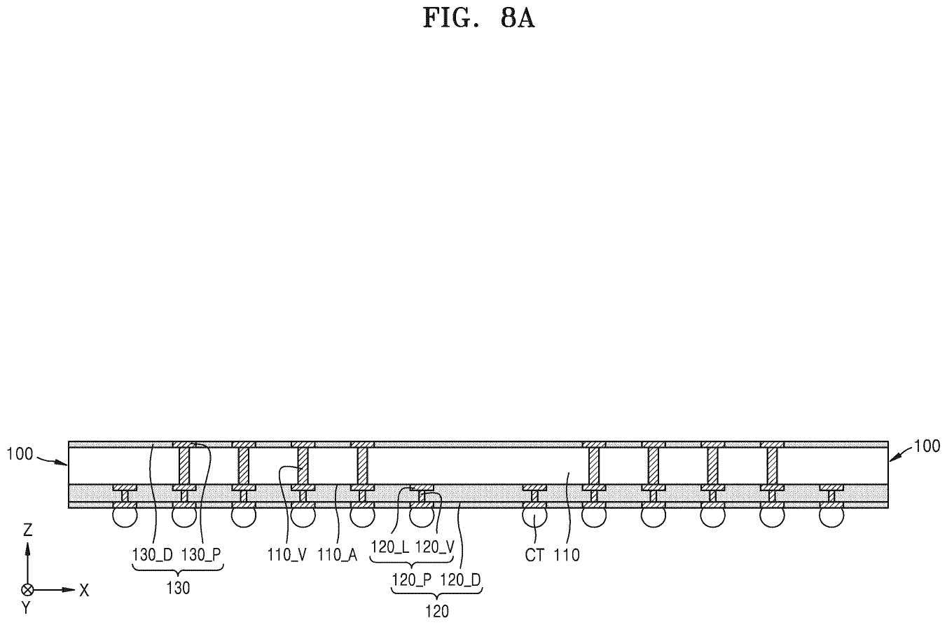

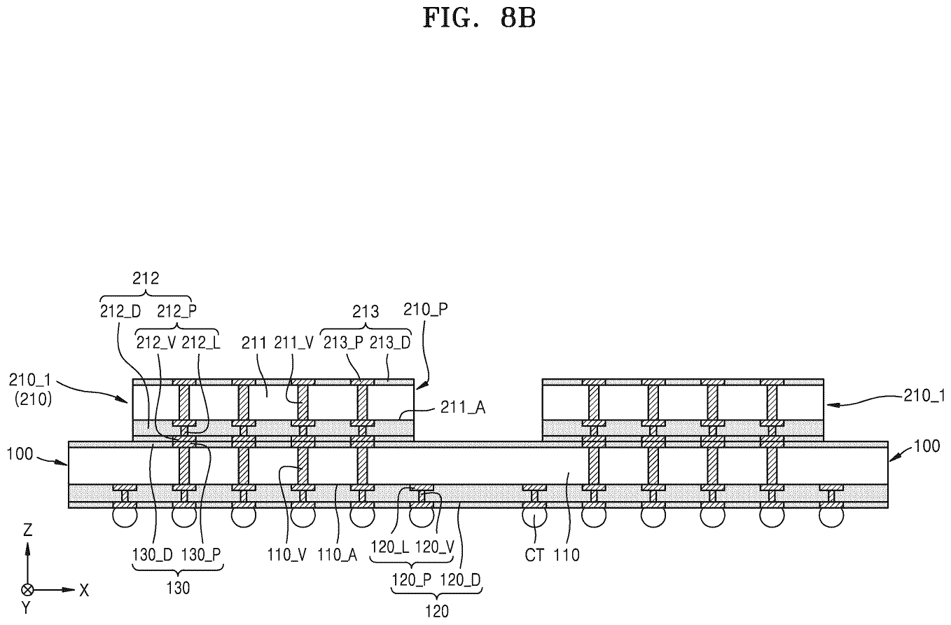

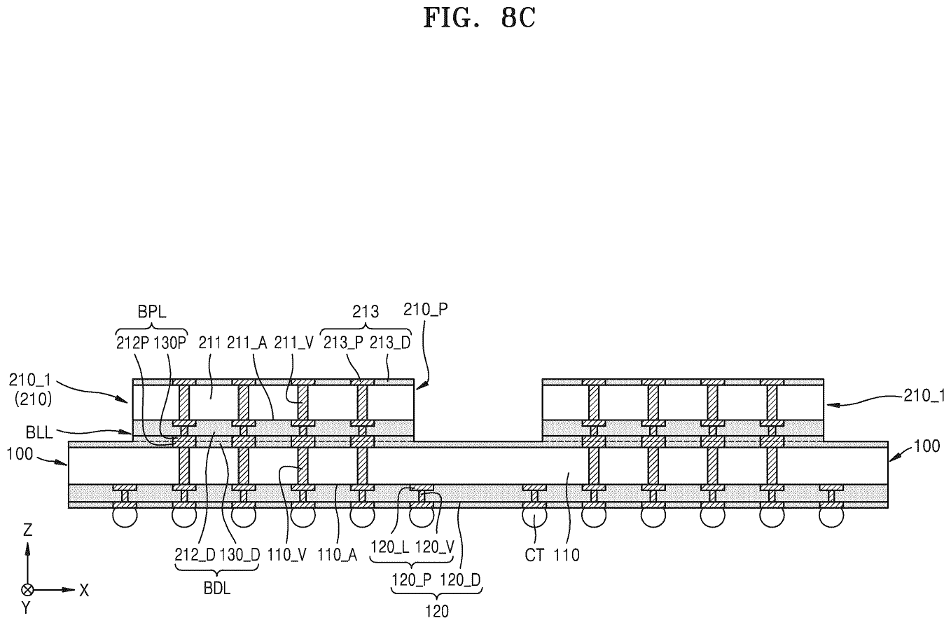

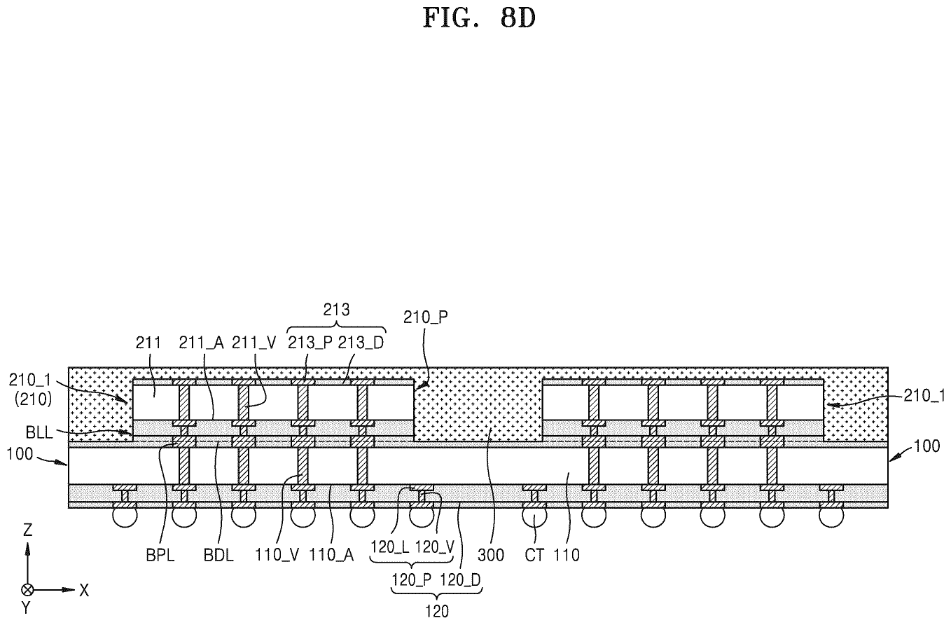

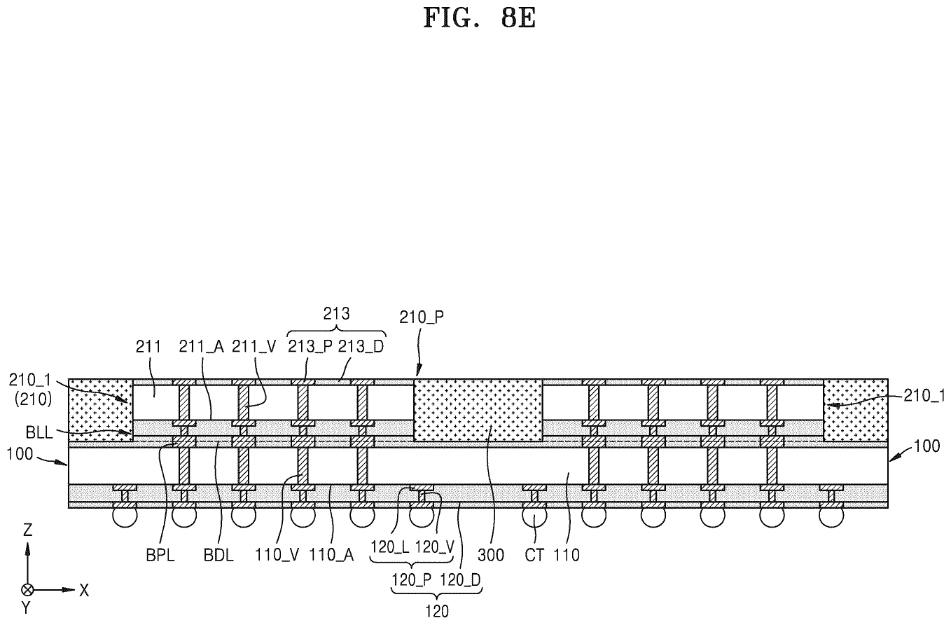

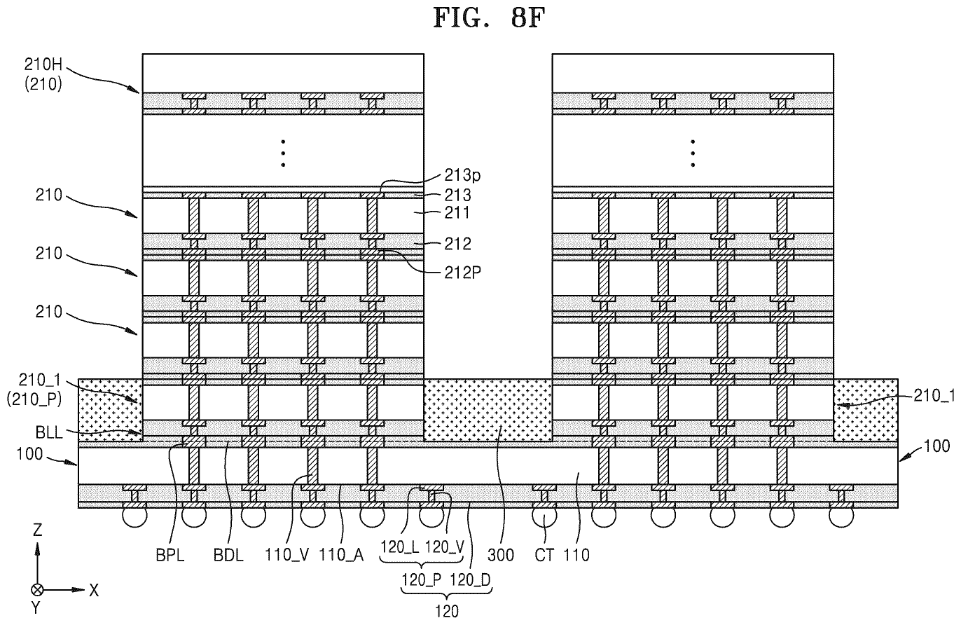

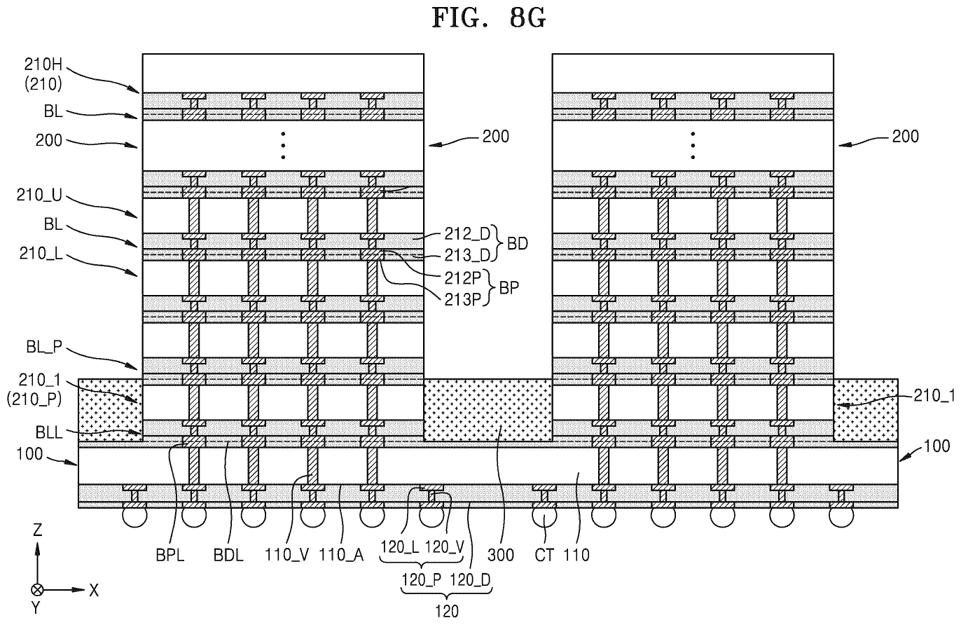

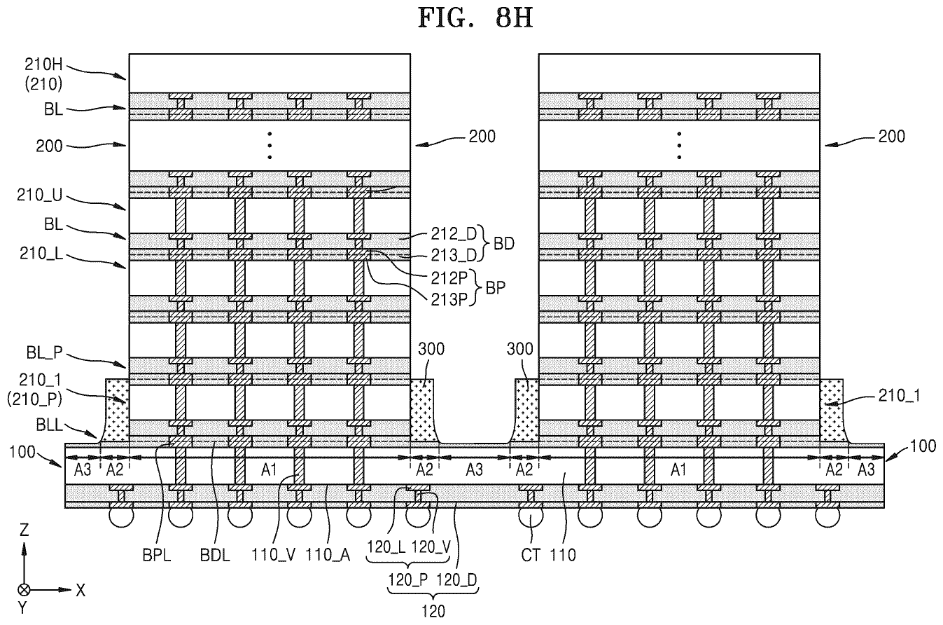

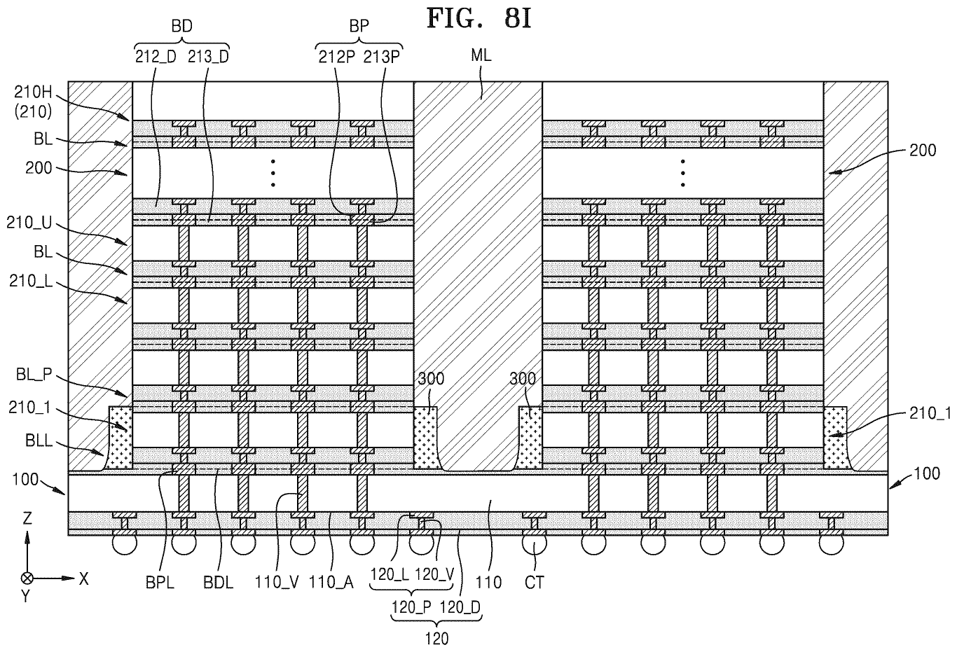

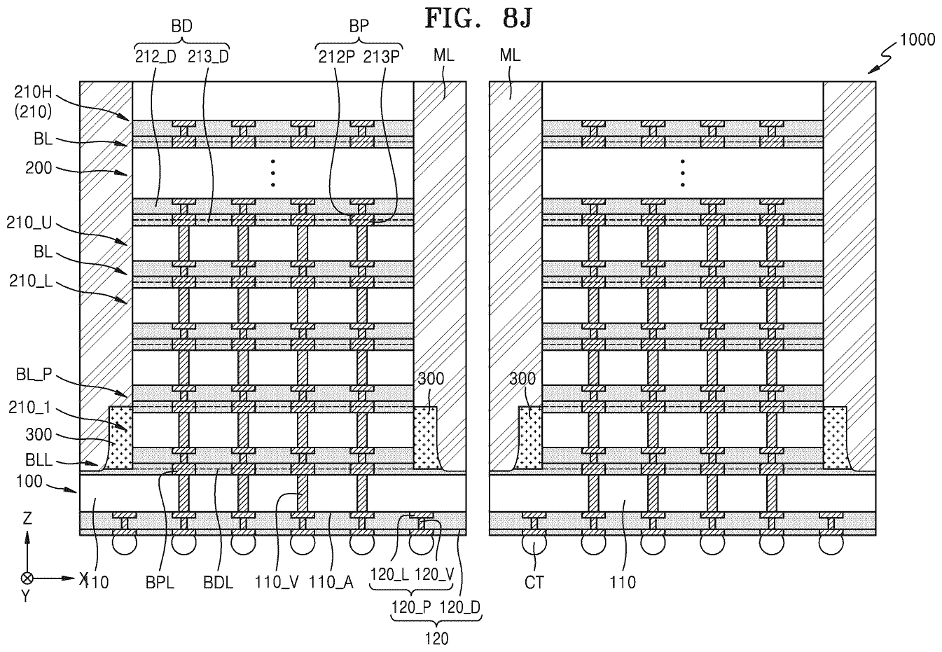

FIGS. 8A through 8J are cross-sectional views illustrating a manufacturing method of the semiconductor package 1000 in sequence, according to implementations. FIGS. 8A to 8J are cross-sectional views sequentially illustrating a method of manufacturing the semiconductor package 1000 in which the lowermost second semiconductor chip 210_1 is the target second semiconductor chip 210_P arranged on the first layer among the plurality of second semiconductor chips 210.

Referring to FIG. 8A, the first semiconductor chip 100 may be provided in plurality. A plurality of first semiconductor chips 100 may be provided in a wafer form in a state of before being diced into the plurality of first semiconductor chips 100. However, the implementation is not limited thereto, and the plurality of first semiconductor chips 100 may be arranged apart from each other on a carrier substrate.

The first semiconductor chip 100 may include the first semiconductor substrate 110, the first through via 110_V, the first lower wiring structure 120, and the first upper wiring structure 130. For example, the active surface 110_A of the first semiconductor substrate 110 may face downward in the vertical direction (Z direction).

In some implementations, the first semiconductor chip 100 may be provided in which external connection terminals CT are attached onto the first lower pad of the first lower wiring structure 120. However, the implementation is not limited thereto, and the external connection terminals CT may be attached onto the first lower pad after the first semiconductor chips 100 are cut into a plurality of semiconductor packages 1000 as disclosed in FIG. 8J.

Referring to FIGS. 8B and 8C, at least one second semiconductor chip 210 may be mounted on and attached onto the first semiconductor chip 100.

In FIGS. 8B and 8C, one second semiconductor chip 210 is illustrated to be mounted on and attached onto each of the plurality of first semiconductor chips 100, but is not limited thereto, and one to four second semiconductor chips 210 may be mounted on and attached onto each of the plurality of first semiconductor chips 100. The target second semiconductor chip 210_P may include the second semiconductor chip 210 arranged uppermost among the second semiconductor chips 210, which have been mounted on and attached thereto in this operation. Referring to FIGS. 8B and 8C, the target second semiconductor chip 210_P may include the lowermost second semiconductor chip 210_1.

The second semiconductor chip 210 may include the second semiconductor substrate 211, the second through via 211_V, the second lower wiring structure 212, and the second upper wiring structure 213. The lowermost second semiconductor chip 210_1 may be mounted on the first semiconductor chip 100 such that the second lower wiring structure 212 of the lowermost second semiconductor chip 210_1 is in contact with the first upper wiring structure 130 of the first semiconductor chip 100. For example, the lowermost second semiconductor chip 210_1 may be mounted on the first semiconductor chip 100 so that the first upper pad 130P of the first semiconductor chip 100 is in contact with the second lower pad 212P of the lowermost second semiconductor chip 210_1.

Thereafter, heat and pressure may be applied to the lowermost second semiconductor chip 210_1, and the lowermost second semiconductor chip 210_1 may be attached onto the first semiconductor chip 100. By applying heat and pressure, a hybrid bonding process may be performed between the second lower wiring structure 212 of the second semiconductor chip 210 and the first upper wiring structure 130 of the first semiconductor chip 100, and the lowermost bonding layer BLL may be formed.

The lowermost bonding layer BLL may include the lowermost bonding pad BPL and the lowermost bonding insulating layer BDL. For example, the lowermost bonding pad BPL may have been integrated by applying a diffusion coupling process using heat on the second lower pad 212P of the lowermost second semiconductor chip 210_1 and the first upper pad 130P of the first semiconductor chip 100, and the lowermost bonding insulating layer BDL may have been integrated by applying a hydrogen coupling process using pressure on the second lower wiring insulating layer 212_D of the lowermost second semiconductor chip 210_1 and the first upper wiring insulating layer 130_D of the first semiconductor chip 100.

Referring to FIGS. 8D and 8E, the support insulating layer 300 may be formed on the resultant product of FIG. 8C.

The support insulating layer 300 may be formed on the lowermost bonding layer BLL to cover the second upper wiring structure 213 of the target second semiconductor chip (refer to 210_P in FIG. 1). In some implementations, the support insulating layer 300 may be formed by performing a deposition process, such as a chemical vapor deposition (CVD) process and a physical vapor deposition (PVD) process.

Thereafter, a portion of the upper surface 300_U of the support insulating layer 300 may be removed so that the second upper wiring structure 213 of the target second semiconductor chip 210_P is exposed. In some implementations, a chemical mechanical polishing (CMP) process may be performed to polish a portion of the support insulating layer 300.

In some implementations, a portion of the second upper wiring structure 213 of the target second semiconductor chip 210_P may be removed together with a portion of the upper surface 300_U of the support insulating layer 300, and the thickness of the second upper wiring structure 213 of the target second semiconductor chip 210_P may be reduced. Accordingly, a thickness of the target second semiconductor chip 210_P may be reduced.

Referring to FIGS. 8F and 8G, the plurality of second semiconductor chips 210 may be mounted on and attached onto the target second semiconductor chip 210_P. In operations disclosed in FIGS. 8F and 8G, the number of second semiconductor chips 210 to be stacked may be 4 to 16.

The plurality of second semiconductor chips 210 may be mounted on the lowermost second semiconductor chip 210_1 so that the side surfaces of the plurality of second semiconductor chips 210 may be aligned with the side surfaces of the lowermost second semiconductor chip 210_1 in the vertical direction (Z direction). For example, the plurality of second semiconductor chips 210 may be stacked so that the second lower wiring structure 212 of the second semiconductor chip 210 to be newly mounted is in contact with the second upper wiring structure 213 of the second semiconductor chip 210 having previously been mounted.

Thereafter, heat and pressure may be applied to the plurality of second semiconductor chips 210, the plurality of chip-to-chip bonding layers BL may be respectively formed between the plurality of second semiconductor chips 210, and thus the plurality of second semiconductor chips 210 may be attached to each other. By applying heat and pressure, a hybrid bonding process may be performed between the second lower wiring structure 212 of the upper layer second semiconductor chip 210U and the second upper wiring structure 213 of the lower layer second semiconductor chip 210_L, and the chip-to-chip bonding layer BL may be formed.

The chip-to-chip bonding layer BL may include the chip-to-chip bonding pad BP and the chip-to-chip bonding insulating layer BD. For example, the chip-to-chip bonding pad BP may become one body by applying a diffusion coupling process using heat on the second lower pad 212P of the upper layer second semiconductor chip 210_L and the second upper pad 213P of the lower layer second semiconductor chip 210_L, and the chip-to-chip bonding insulating layer BD may become one body by applying a hydrogen coupling process using pressure on the second lower wiring insulating layer 212_D of the upper layer second semiconductor chip 210_U and the second upper wiring insulating layer 213_D of the lower layer second semiconductor chip 210_L.

For example, the target chip-to-chip bonding layer BL_P may include the chip-to-chip bonding layer BL including the second upper wiring structure 213 of the target second semiconductor chip 210_P. For example, the target chip-to-chip bonding layer BL_P may be thinner than the other chip-to-chip bonding layers BL. For example, the vertical level of the upper surface 300_U of the support insulating layer 300 may be lower than the vertical level of the upper surface of the target chip-to-chip bonding layer BL_P, and may be higher than the vertical level of the lower surface of the target chip-to-chip bonding layer BL_P.

When five or more second semiconductor chips 210 are mounted on and attached onto the first semiconductor chip 100 at a time, a peeling phenomenon may occur between the first semiconductor chip 100 and the lowermost second semiconductor chip 210_1. Between operations of mounting the plurality of second semiconductor chips 210 on the first semiconductor chip 100, by adding an operation of forming the support insulating layer 300 for fixing the first semiconductor chip 100 and the lowermost second semiconductor chip 210_1, a peeling phenomenon between the first semiconductor chip 100 and the lowermost second semiconductor chip 210_1 may be suppressed.

Referring to FIG. 8H, a portion of the support insulating layer 300 may be etched to expose a portion of the upper surface of the lowermost bonding layer BLL. In some implementations, the support insulating layer 300 may be partially removed by using a blade cutting method.

For example, a region of the lowermost bonding layer BLL, which overlaps the support insulating layer 300 in the vertical direction (Z direction), may include the edge region A3 of the lowermost bonding layer BLL. For example, in the process of removing a portion of the support insulating layer 300, a portion of the edge region A3 of the lowermost bonding layer BLL may also be removed together. Accordingly, a thickness of the edge region A3 of the lowermost bonding layer BLL may be less than thicknesses of the center region A1 of the lowermost bonding layer BLL and the connection region A2 of the lowermost bonding layer BLL.

Referring to FIGS. 8I and 8J, after the molding layer ML is formed, the molding layer ML and the first semiconductor substrate 110 may be cut.

The molding layer ML may be formed on the lowermost bonding layer BLL to cover the stacked structure 200 and the support insulating layer 300. The molding layer ML may protect the stacked structure 200 and the first semiconductor chip 100 from external impact. For example, a portion of the molding layer ML may be removed so that the upper surface of the stacked structure 200 is exposed. Accordingly, the upper surface of the stacked structure 200 may be coplanar with the upper surface of the molding layer ML.

Thereafter, by cutting the resultant product of FIG. 8I along a dicing line, the plurality of semiconductor packages 1000 may be manufactured. For example, the dicing line may be arranged in the edge region A3 of the lowermost bonding layer BLL. For example, the dicing line may be adjusted so that the support insulating layer 300 is arranged inside the molding layer ML, and is not exposed to the outside.

While the present disclosure has been particularly shown and described with reference to implementations thereof, it will be understood that various change in form and details may be made therein without departing from the spirit and scope of the following claims.

What is claimed is:

1. A semiconductor package comprising:
a first semiconductor substrate;
a stacked structure including:
a plurality of second semiconductor substrates on the first semiconductor substrate, and
a plurality of chip-to-chip bonding layers respectively arranged between the plurality of second semiconductor substrates;
a lowermost bonding layer including side surfaces aligned with side surfaces of the first semiconductor substrate in a vertical direction, the lowermost bonding layer being arranged between the first semiconductor substrate and a lowermost second semiconductor substrate of the plurality of second semiconductor substrates;
a support insulating layer on the lowermost bonding layer, the support insulating layer including an upper surface that has a higher vertical level than a vertical level of an upper surface of the lowermost second semiconductor substrate; and
a molding layer on the lowermost bonding layer, the molding layer surrounding the support insulating layer and the stacked structure.

2. The semiconductor package of claim 1,
wherein the plurality of chip-to-chip bonding layers of the stacked structure comprise a target chip-to-chip bonding layer, and
wherein the upper surface of the support insulating layer is between an upper surface of the target chip-to-chip bonding layer and a lower surface of the target chip-to-chip bonding layer along the vertical direction.

3. The semiconductor package of claim 2, wherein a thickness of the target chip-to-chip bonding layer is less than a thicknesses of each of remaining chip-to-chip bonding layers of the plurality of chip-to-chip bonding layers.

4. The semiconductor package of claim 2,
wherein the stacked structure comprises a plurality of layers, each layer comprising a respective second semiconductor substrate of the plurality of second semiconductor substrates, a number of the plurality of layers being eight to twenty, and
wherein the target chip-to-chip bonding layer is below a second semiconductor substrate of the plurality of second semiconductor substrates that is arranged on a fifth layer of the plurality of layers, and first to fourth layers of the plurality of layers are between the fifth layer and the first semiconductor substrate.

5. The semiconductor package of claim 1,
wherein the support insulating layer overlaps an upper surface of the lowermost bonding layer in the vertical direction, and
wherein the lowermost bonding layer comprises
a center region that overlaps the stacked structure in the vertical direction,
a connection region that overlaps the support insulating layer in the vertical direction, and
an edge region that extends beyond edges of side surfaces of the support insulating layer.

6. The semiconductor package of claim 5,
wherein a thickness of the center region of the lowermost bonding layer is greater than a thickness of the connection region of the lowermost bonding layer, and
wherein the thickness of the connection region of the lowermost bonding layer is greater than a thickness of the edge region of the lowermost bonding layer.

7. The semiconductor package of claim 6,
wherein the lowermost bonding layer comprises a recess side surface that connects an upper surface of the edge region of the lowermost bonding layer to an upper surface of the connection region of the lowermost bonding layer, and
wherein the recess side surface of the lowermost bonding layer is continuously connected to a first side surface of the side surfaces of the support insulating layer.

8. The semiconductor package of claim 7,
wherein the first side surface of the support insulating layer comprises a curved side surface with a concave shape, and
wherein the recess side surface of the lowermost bonding layer is continuously connected to the curved side surface of the support insulating layer, and the recess side surface of the lowermost bonding layer has a concave shape.

9. The semiconductor package of claim 1, wherein a width of the support insulating layer increases toward the lowermost bonding layer.

10. The semiconductor package of claim 1, wherein the upper surface of the support insulating layer has a concave shape.

11. The semiconductor package of claim 1,
wherein the upper surface of the support insulating layer comprises a first upper surface and a second upper surface, the first upper surface and the second upper surface defining a step,
wherein the first upper surface of the support insulating layer is in contact with the stacked structure, and
wherein the second upper surface of the support insulating layer has a vertical level lower than a vertical level of the first upper surface of the support insulating layer, and the first upper surface is between the second upper surface and the stacked structure.

12. The semiconductor package of claim 1,
wherein side surfaces of the molding layer are aligned with side surfaces of the first semiconductor substrate and side surfaces of the lowermost bonding layer in the vertical direction, and
wherein an upper surface of the molding layer is coplanar with an upper surface of the stacked structure.

13. A semiconductor package comprising:
a first semiconductor chip including a first semiconductor substrate, a first through via extending through the first semiconductor substrate, and a first upper wiring structure on an upper surface of the first semiconductor substrate;
a stacked structure on the first semiconductor chip and including a plurality of second semiconductor chips, wherein each of the plurality of second semiconductor chips includes a second semiconductor substrate, a second through via extending through the second semiconductor substrate, a second lower wiring structure under the second semiconductor substrate, and a second upper wiring structure on an upper surface of the second semiconductor substrate;
a support insulating layer on the first semiconductor chip and surrounding at least a portion of side surfaces of the plurality of second semiconductor chips; and
a molding layer on the first semiconductor chip, the molding layer surrounding the support insulating layer and the stacked structure.

14. The semiconductor package of claim 13,
wherein the first upper wiring structure of the first semiconductor chip and the second lower wiring structure of a lowermost second semiconductor chip of the stacked structure are in direct contact with each other and define a body,
wherein side surfaces of the second lower wiring structure of the lowermost second semiconductor chip are on an upper surface of the first upper wiring structure of the first semiconductor chip, and
wherein the support insulating layer is in contact with the side surfaces of the second lower wiring structure of the lowermost second semiconductor chip.

15. The semiconductor package of claim 13,
wherein a center region of the first upper wiring structure of the first semiconductor chip is in contact with a lowermost second semiconductor chip of the stacked structure,
wherein a connection region of the first upper wiring structure of the first semiconductor chip is in contact with the support insulating layer,
wherein an edge region of the first upper wiring structure of the first semiconductor chip is in contact with the molding layer, and
wherein a thickness of the edge region of the first upper wiring structure of the first semiconductor chip is less than each of a thickness of the connection region and a thickness of the center region of the first upper wiring structure.

16. The semiconductor package of claim 13,
wherein the stacked structure comprises a plurality of layers, each layer comprising a respective second semiconductor chip of the plurality of second semiconductor chips, a number of the plurality of layers being eight to twenty,
wherein the plurality of second semiconductor chips comprise a target second semiconductor chip,
wherein an upper surface of the support insulating layer is coplanar with an upper surface of the target second semiconductor chip, and
wherein the target second semiconductor chip is on a layer of first through fourth layers of the plurality of layers, and the first through fourth layers of the plurality of layers are between a fifth layer of the plurality of layers and the first semiconductor substrate.

17. The semiconductor package of claim 16,
wherein a thickness of the target second semiconductor chip is less than a thicknesses of each of remaining second semiconductor chips of the plurality of second semiconductor chips.

18. A semiconductor package comprising:
a first semiconductor substrate;
a stacked structure including a plurality of second semiconductor substrates on the first semiconductor substrate, and a plurality of chip-to-chip bonding layers respectively arranged between the plurality of second semiconductor substrates;
a lowermost bonding layer including side surfaces aligned with side surfaces of the first semiconductor substrate in a vertical direction, the lowermost bonding layer being between the first semiconductor substrate and a lowermost second semiconductor substrate of the plurality of second semiconductor substrates;
a support insulating layer on the lowermost bonding layer and surrounding a portion of side surfaces of the stacked structure; and
a molding layer on the lowermost bonding layer, the molding layer surrounding the support insulating layer and the stacked structure,
wherein each of the plurality of chip-to-chip bonding layers comprises a chip-to-chip bonding insulating layer between corresponding adjacent second semiconductor substrates of the plurality of second semiconductor substrates, and a chip-to-chip bonding pad inside the chip-to-chip bonding insulating layer,
wherein the lowermost bonding layer comprises a lowermost bonding pad and a lowermost bonding insulating layer surrounding the lowermost bonding pad,
wherein the plurality of chip-to-chip bonding layers comprise a target chip-to-chip bonding layer, an upper surface of the support insulating layer is between an upper surface of the target chip-to-chip bonding layer and a lower surface of the target chip-to-chip bonding layer in the vertical direction, and
wherein the target chip-to-chip bonding layer is on a layer of first through fourth layers of the plurality of chip-to-chip bonding layers.

19. The semiconductor package of claim 18,
wherein the upper surface of the support insulating layer has a concave shape, and
wherein a thickness of the target chip-to-chip bonding layer is less than a thicknesses of each of remaining chip-to-chip bonding layers of the plurality of chip-to-chip bonding layers.

20. The semiconductor package of claim 18,
wherein the support insulating layer overlaps an upper surface of the lowermost bonding layer in the vertical direction,
wherein an edge region of the lowermost bonding layer is in contact with the molding layer, and
wherein a thickness of the edge region of the lowermost bonding layer is less than a thicknesses of a remaining region of the lowermost bonding layer.
